(19) United States
(12) Patent Application Publication
(10) Pub. No.: US 2008/0095385 A1
(43) Pub. Date: Apr. 24, 2008

(54) Method of and System for Automatically Adjusting the Loudness of an Audio Signal

(75) Inventor: Bruno Korneel Tourwe, Berchem (BE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/570,799

(22) PCT Filed: Jun. 13, 2005
(86) PCT No.: PCT/IB05/51942

§ 371 Date: Dec. 18, 2006

(30) Foreign Application Priority Data
Jun. 30, 2004 (EP) 04103071.9

(51) Int. Cl. H03G 3/00

(52) U.S. Cl. 381/107

(57) ABSTRACT

The invention describes a method of automatically adjusting the loudness of an audio signal, which method comprises calculating loudness measures for samples of the input audio signal (1), identifying a number of distinct loudness lines (L₁, L₂, L₃, L₄) over 5 time among the loudness measures and altering the samples of the input audio signal (1) according to the identified loudness lines (L₁, L₂, L3, L₄) to give an output audio signal (5) with adjusted loudness.

### FIELD OF THE INVENTION

The invention relates to a method of automatically adjusting the loudness of an audio signal.

The invention further relates to a system for automatically adjusting the loudness of an audio signal.

The invention further relates to an automatic loudness control device for adjusting the loudness of an audio signal.

### BACKGROUND OF THE INVENTION

A number of methods have been developed in an attempt to control the loudness levels of audio signals, known as automatic levelling or automatic equalisation. Existing automatic levelling features claiming to perform an auto-levelling task use compression/expansion algorithms in order to increase the loudness of silent parts of an audio signal and decrease the loudness of strident parts of the signal. These algorithms typically look at the instantaneous amplitude of the audio waveform of the music and modify the amplitude to compensate for excessive or insufficient loudness by applying a suitable value of gain to the output. For example, U.S. Pat. No. 5,892,834 suggests a method for limiting the loudness of the output of a CD player in an automotive environment, whereby the instantaneous amplitude of the audio signal is examined to see if it exceeds a certain threshold. If the threshold is exceeded, the amplitude of the audio signal is attenuated to give a modified output signal.

However, the choice of gain increase or release time—the time it takes to increase or decrease the gain to its target level—is accompanied by problems of its own. Using a short gain increase or release time typically results in “pumping effects” which arise as a result of the rapid switching between low and high levels of gain. Pumping effects result in an output signal with loud transients followed by a marked decrease in the loudness, resulting in a signal which is uncomfortable to listen to. Using a longer gain increase time reduces the pumping effects to some extent, but the performance of the gain adjustment function is reduced as a result, since it then takes too long for the volume of the output signal to be effectively amplified or attenuated. In either case, the resulting output signal is uncomfortable to listen to because of the resulting distortion.

### OBJECT AND SUMMARY OF THE INVENTION

Therefore, an object of the present invention is to provide a method and system which can be used to automatically equalise the level of loudness of an audio signal while preserving the nature of the audio signal, particularly without distorting the signal.

To this end, the present invention provides a method of automatically adjusting the loudness of an audio signal, which method comprises calculating loudness measures for samples of the input audio signal, identifying a number of distinct loudness lines over time among the loudness measures, and altering the samples of the audio signal according to the identified loudness lines to give an output audio signal with adjusted loudness.

Thereby, a “loudness line” is a way of describing the characteristics of a loudness trend, such as duration, rate of change etc. in loudness of the audio signal, which will generally vary over time, growing louder in parts, becoming quieter in other parts, and maintaining an essentially constant loudness in yet other parts. These tendencies to grow louder or quieter or to stay the same can be described as trends which the audio signal follows.

An appropriate system for automatic adjustment of the loudness of an audio signal comprises a calculation unit for calculating loudness measures for samples of the input audio signal, an identifier unit for identifying a number of distinct loudness lines among the loudness measures, and an alteration unit for altering the samples of the audio signal according to the identified loudness lines to give an output audio signal with adjusted loudness.

The method and the system thus provide an easy way of automatically adjusting the level of loudness of an audio signal, providing a listener with an undistorted audio signal of essentially uniform loudness, and obviating the need for the listener to manually adjust the loudness. Since the invention identifies trends in loudness followed by the audio signal and adjusts the loudness of the audio signal accordingly, the adjusted output signal is free of any undesirable pumping effects which characterise existing methods. The experience of listening to music and to radio or TV programs, for example, is considerably improved by the invention since the jarring effects of pronounced loudness changes between programs, commercials or pieces of music etc. are diminished, and the overall level of loudness remains essentially constant. In other applications, for example headsets or in-ear monitors, the automatic loudness adjustment can be used to quickly and automatically adjust the loudness of an audio signal so that it does not exceed a certain threshold, ensuring that the listener does not suffer hearing damage as a result of over-loud signals.

The dependent claims and the subsequent description disclose particularly advantageous embodiments and features of the invention.

The “audio signal” may be any signal which might originate from any audio signal source, preferably digital, such as, for example, an antenna or satellite receiver; an audio input to a device such as radio, television or loudspeaker; a music data file; an MP3 music file etc. The audio signal might also originate from an analog source such as a microphone, and be subsequently converted into digital form suitable for further processing, by sampling in the usual manner.

Loudness is a subjective measure relating to the physical sound pressure level as perceived by the human ear. Research has resulted in several complex mathematical methods to model the human perception of loudness, but these methods are quite time-intensive to perform, so that they are unsuitable for application in a real-time situation. Therefore, in a preferred embodiment of the present invention, use is made of the fact that loudness is strongly related to the energy of sound, so that a measure of the energy of the audio signal, which is relatively simple to calculate, is used instead of the more complex mathematical models. In a particularly preferred embodiment of the invention, the root-mean-square (RMS) value, calculated using the amplitude of the samples of the digital input signal, is used as a representative mathematical model for loudness perception. The RMS value calculated for a number of consecutive samples is thus a representative loudness measure for these samples. In this type of calculation, the absolute value of the amplitude of a sample is used. In addition or as alternative to the RMS calculation, the absolute value of the sample can be directly used as a loudness measure. Here, a low pass filter preferably follows the absolute value calculation to smoothen the dynamic behaviour of the input signal.

As time progresses, the number of calculated loudness measures increases. Were these loudness measures to be plotted against time, they would appear to form clusters or groups. One group might appear to merge into a neighbouring group, or it might be clearly distinct from a neighbouring group. The method of the present invention preferably identifies a distinct trend or loudness line for each of the groups of loudness measures. The groups of loudness measures correspond to sections of the audio signal which can be distinguished from each other on the basis of loudness. For example, a group of loudness measures may appear to follow a trend of increasing or decreasing magnitude, it may appear to remain more or less constant over time, or it might be positioned markedly higher or lower than its neighbours. In a preferred embodiment a new group might also be established as soon as a user performs a certain type of action which is usually accompanied by an immediate change in loudness, for example by switching channels on a television, by manually changing the volume by turning a knob or pressing the appropriate button on a remote control, or by switching to another track on an audio listening device such as an MP3 player.

The method of the present invention applies the information obtained by interpreting the characteristics of the loudness lines to adjust the loudness of the audio signal, e.g. by adjusting the gain of the appropriate samples. To determine the degree of gain adjustment necessary, a reference level of loudness might be predefined, or might be specified by the user. For example, some listeners might like to have the overall level of loudness relatively quiet, whereas other listeners might prefer a louder volume to be maintained over time. A maximum loudness level and/or a minimum loudness level may be defined, or it may suffice to define an average overall level of loudness.

To determine which adjustments are to be made to the samples of the input audio signal to give an output audio signal of the desired loudness, the present invention determines the characteristics of the loudness lines, such as slope and relative position. For example, a loudness line rising more steeply or positioned higher than the preceding loudness line would indicate that the overall level of loudness of the input signal has increased. The amplitudes of the samples related to this group are adjusted so that the loudness of the corresponding part of the output audio signal is attenuated. Similarly, if a loudness line for part of the input audio signal has been identified as being below a minimum desired level of loudness, the corresponding samples are amplified so that the loudness of the output audio signal is increased over that part.

The attenuation or amplification of the audio samples may preserve the slope of the loudness lines, or may also compensate for this. For example, if a loudness line indicates that the corresponding group is too loud while also being of decreasing loudness, the corresponding samples might all be attenuated by the same amount, so that the decreasing loudness is reflected in the output audio signal, or the gain might be attenuated by ever smaller values, so that the output audio signal maintains a relatively constant level of loudness over the corresponding section.

In a preferred embodiment of the invention, a loudness measure is identified as belonging to a group if its value lies within a predefined margin of tolerance for the group. This margin of tolerance can be a constant value, or might be configured by the user. A lower margin of tolerance might result in a greater number of distinct loudness lines being identified, whereas a higher margin of tolerance might reduce the overall number of identified loudness lines. The margin of tolerance might therefore be regarded as a measure of the quality of performance of the system, since a lower margin results in a correspondingly greater number of adjustments to the output audio signal.

A number of known methods might be applied to calculate the loudness lines for a group of loudness measures. The loudness lines need not necessarily be straight lines, but might equally be curves of second order or higher, which best fit the trend of the group. However, since a more simple method allows faster computation, a preferred embodiment of the invention applies a technique of linear interpolation or mean calculation on the loudness measures of the group to identify a distinct loudness line within a group of consecutive loudness measures.

The present invention can be applied in a real-time situation, such as automatically adjusting the loudness of a television audio output signal or an in-ear monitor signal. However, the invention can also be applied to pre-scan audio signals so that the necessary gain adjustment values can be calculated in advance of listening to the audio signal.

Use of the invention in pre-scanning mode permits a higher level of computational accuracy, since the results do not have to be available immediately. One example of such an application might be to calculate in advance the gain adjustments to be made to a number of songs in a music collection, stored, for example, on a portable storage device, on a computer or on a portable audio device, so that an overall loudness level is maintained during playback of the songs. In another example, the gain adjustments to be made to the loudness of the audio content of a television recording can be calculated in advance, so that the listener can enjoy a predefined level of overall loudness when viewing the recording at a later date.

The values of gain adjustment can be stored, along with all the information required to apply these gain adjustment values, together with the audio information, or in a separate data file. For example, the values of gain adjustment and any associated information might be stored in the header of an MP3 music file or in the MP3 stream itself in a form suitable for application at a later time. Alternatively, the values of gain adjustment and any associated information might be stored in a separate file, linked in some way to the audio file to which they are to be applied.

In a further embodiment of the invention, the gain adjustment values might be directly applied to the samples of the input audio signal and stored in a modified audio file. If the input audio signal originates from an audio file, this audio file might remain unchanged, or might be replaced by the modified audio file.

The system for automatic loudness adjustment can be realised in any audio processing device, which might be a stand-alone device for loudness adjustment purposes only and located, for example, between a satellite receiver or set-top box and a loudspeaker for automatic adjustment of television volume. Here, an audio processing device is understood to be any device with a line input for an audio signal and a means of performing signal processing, preferably digital, on the audio signal. Equally, the system for automatic loudness adjustment may be incorporated as part of another device in which it automatically ensures an even loudness level for the user, for example in one of the aforementioned devices or in a telephone, a walkman, an in-ear monitor, or any kind of device with a loudspeaker or audio line output.

In a further realisation, the automatic loudness adjustment system might also feature a means for storing a loudness-adjusted signal and/or the information describing the loudness adjustments to an internal or external memory. Therefore, an “automatic loudness adjustment system” is to be understood as a system that can process an audio input signal to calculate any required loudness adjustments and can apply these adjustments to give the desired output signal, and/or store the information to a memory storage device.

For example, in a preferred application, an automatic loudness adjustment system might be incorporated in a car radio, so that the volume of the radio station remains at a relatively constant level, even when automatically changing stations over different broadcast regions. In another application, such an automatic loudness adjustment system might be incorporated in a telephone so that the loudness of the output via the loudspeaker does not exceed a desired threshold, ensuring that the person using the telephone is not subject to the irritating and often uncomfortable effects of a very loud speaker at the other end, or loud music when being placed on hold. One application, which will be appreciated by many users, is the use of such an automatic loudness adjustment device in conjunction with a television, so that the loudness of the commercials no longer exceeds the loudness of the preceding and subsequent program content.

A system for automatic loudness adjustment according to the present invention or an audio processing device comprising such a system might perform some of the processing steps described above by implementing software modules or computer program products. Such a computer program product might be directly loadable into the memory of a programmable audio processing device, such as might be found in a home hi-fi system, PC, telephone, walkman, etc. Some of the units for buffering the input audio signal, calculating the RMS values, calculating the group means and filtering the adjustment values can thereby be realised in the form of computer program modules. Since any required software or algorithms might be encoded on a processor of a hardware device, an existing audio processing device might easily be adapted to benefit from the features of the invention. Alternatively, some of the units described can equally be realised, where appropriate, by using hardware modules.

The audio signal and its associated loudness lines and/or gain adjustment values may be stored on a memory device according to the invention. Such a memory device might be for example, a CD, a hard-disk, a DVD, a memory stick etc. The loudness lines and/or gain adjustment values might be incorporated in a data file with the audio signal, or might be stored in a separate sector or block of memory. In this case, the audio processing device ultimately used to render the audio signal into audible sound need not comprise a calculation unit for calculating the loudness measures and an identifying unit for identifying the loudness lines. It suffices that this audio processing device can retrieve from memory the previously calculated loudness lines and/or gain adjustment values associated with an audio signal and apply them to the audio signal before passing the modified signal to a loudspeaker.

Other objects and features of the present invention will become apparent from the following detailed descriptions considered in conjunction with the accompanying drawing. It is to be understood, however, that the drawing is designed solely for the purposes of illustration and not as a definition of the limits of the invention.

### BRIEF DESCRIPTION OF THE DRAWINGS

FIG. 1 is a block diagram of a system for automatic loudness adjustment according to an embodiment of the present invention;

FIG. 2 shows a graph of loudness measures plotted against time;

FIG. 3a shows a graph of an audio signal, with amplitude plotted against time;

FIG. 3b shows a graph of an adjusted audio signal, with amplitude plotted against time;

FIG. 4 is a block diagram showing an application using a system for automatic loudness adjustment according to an embodiment of the present invention;

FIG. 5 is a flowchart showing the steps in a method of real-time processing of an audio signal;

FIG. 6 is a flowchart showing the steps in a method of advance processing of an audio signal;

FIG. 7 is a flowchart showing the steps in a method of determining transition times during advance processing of an audio signal.

### DESCRIPTION OF EMBODIMENTS

In the description of the following figures, like numbers refer to like objects.

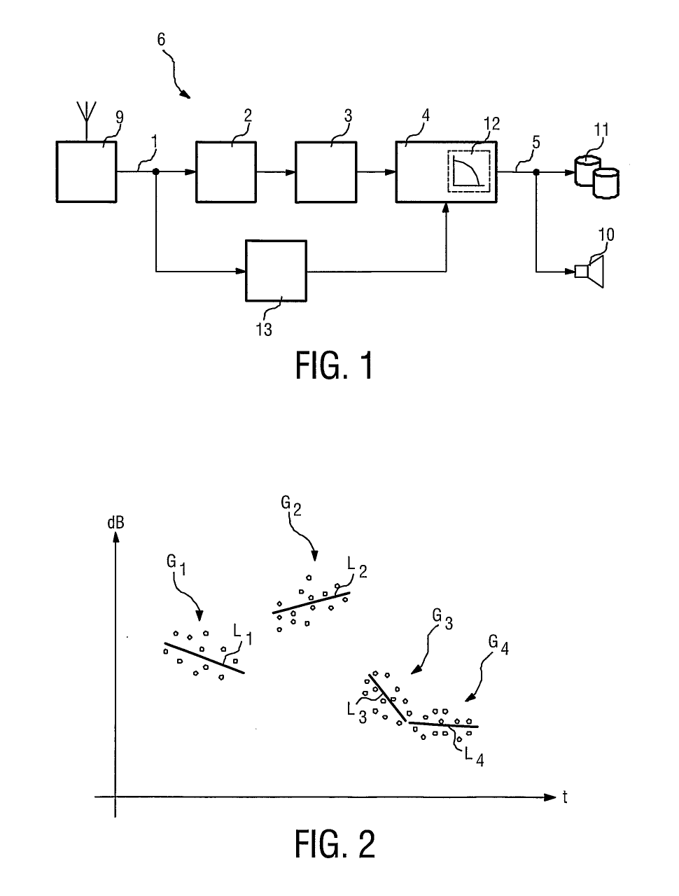

FIG. 1 shows a simple block diagram of system 6 for automatic adjustment of the loudness of an audio signal, illustrating the basic steps involved in analysing the input audio signal 1 to give an audio output signal 5 with adjusted loudness. The input audio signal 1 might originate from a source 9 such as a receiver, a database etc., and is in a sampled digital form. The output audio signal 5 can be forwarded to a loudspeaker 10 or might be stored in a database 11 for playback at a later point in time.

In a first processing step, a calculation unit 2 calculates loudness measures for samples of the input audio signal 1. The loudness measures are essentially calculated one after another if the system 6 is being used in a real-time situation, or they might be calculated in a parallel or batch mode if the system is being used in a pre-scanning application.

In this embodiment, the RMS (root mean square) is calculated for the samples of the input audio signal 1, according to

$$RMS = \frac{1}{N} \sqrt{{\sum }_{i = 1}^{N} {( {x}_{i} - \overline{x} )}^{2}} \qquad ( 1 )$$

where
xᵢ is the amplitude of the ith sample;
N is the number of samples over which the RMS is calculated.

x̅, which is the average of all xᵢ's, is given by

$$\overline{x} = \frac{1}{N} {\sum }_{i = 1}^{N} {x}_{i} \qquad ( 2 )$$

The value of N is determined by the magnitude of the buffer used to buffer the samples of the input signal, and the sampling rate of the audio signal. For example, for a buffer of 0.1 s and a sample rate of 44100 Hz, N would be 4410. A general expression for N is

N=Fs·BL,

Fs being the sample rate expressed in hertz (Hz),

BL being the size of the buffer in seconds.

For normal audio signals (like music) without a DC bias, the average x̅ in equation (2) is zero, so that the formula is reduced to summing all the squared values of amplitude xᵢ for the N samples being considered for this RMS value, taking the square root of the sum and dividing this by the number of samples N, as given by equation (1).

For the purposes of illustration, the RMS values are shown plotted against time in FIG. 2. Each point in the graph represents one RMS value calculated using the amplitudes of a number of samples. It can clearly be seen that the points form clusters or groups G₁, G₂, G₃, G₄. The groups G₁, G₂, G₃, G₄ might be clearly separate from one another, like groups G₁and G₂, or one group might lead into another, such as G₃ and G₄.

The RMS values are forwarded to a following identification unit 3, which examines the relationship of each RMS value to the previous RMS values in order to determine whether the current RMS value is sufficiently close to the previous ones. To this end, the identification unit 3 compares the current RMS value with a previously calculated mean value. If Cₘ represents the current mean of the current group G₁, G₂, G₃, G₄, and Cᵣ is a margin of tolerance or allowed deviation, then the decision comes down to checking the inequality

Cₘ−Cᵣ≦RMS≦Cₘ+Cᵣ (3)

the current RMS value satisfies this inequality, it is included in the group G₁, G₂, G₃, G₄, and the mean Cₘ of the group G₁, G₂, G₃, G₄ is updated accordingly.

Alternatively, Cₘ could also represent the next expected RMS value, based on the existing trend of the group G₁, G₂, G₃, G₄.

By applying an appropriate technique of linear interpolation or mean calculation, the identification unit 3 calculates a “loudness line” L₁, L₂, L₃, L₄ for the current group G₁, G₂, G₃, G₄. The loudness line L₁, L₂, L₃, L₄ for a group G₁, G₂, G₃, G₄, shown as straight lines drawn through the clusters of points in the graph of FIG. 2, is a linear indication of the trend taken by the loudness of the audio signal 1 over time. The slope of the loudness line indicates whether the audio signal 1 is becoming quieter or louder, or whether the level of loudness of the audio signal 1 is being maintained. The equation for a loudness line y can be expressed as

y(t)=b+a·t (4)

where
b is the gain at the beginning of the group (dB),
a is the slope of the loudness line, i.e. the change in gain per second (dB/s),
t is a measure of time (s).

Once loudness lines L₁, L₂, L₃, L₄ for this signal 1 have been identified, an alteration unit 4 can apply this information to alter the samples of the audio signal 1. If the system is being operated in a real-time application, the alteration unit performs the adjustments to the samples of the audio signal. In a pre-scanning mode, the alteration unit 4 may first carry out any adjustments after all the loudness lines have been calculated. The alteration unit 4 calculates the gain to be applied to each sample in order to maintain a predefined loudness level over the entire output audio signal 5. The gain to be applied over time is calculated by the following formula

g(t)=−{y(t)+LT} (5)

where
g is interpolated gain value (dB),

LT is a threshold value (typically 10 dB)

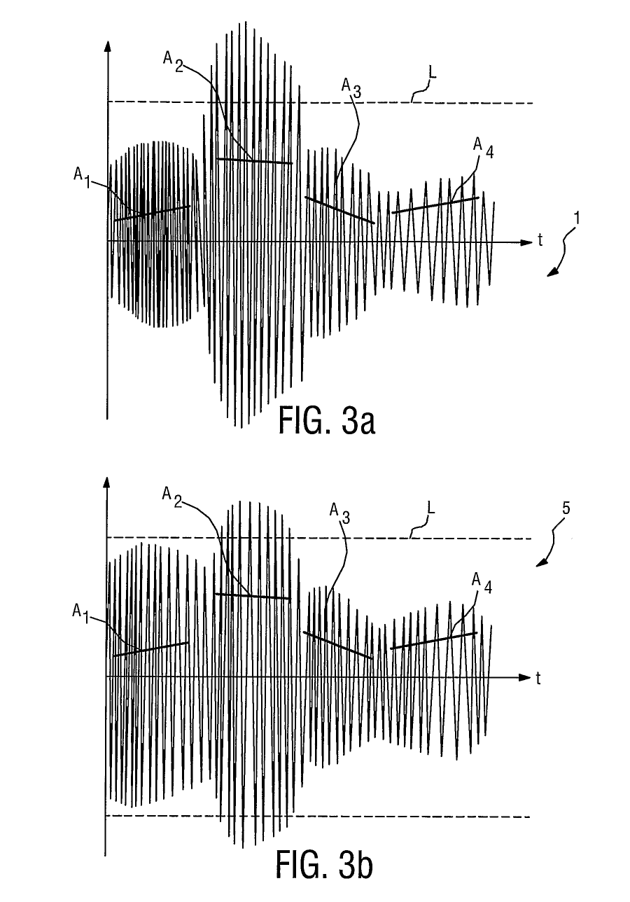

FIG. 3a shows an input audio signal 1, featuring fluctuations over time in the overall loudness of the signal. A dashed line indicates the desired overall loudness level L. It is evident that parts of the audio signal deviate considerably from this level L.

After processing the audio signal 1 and adjusting the gain for the samples of the output audio signal 5 in the system 6, the resulting audio signal 5 appears as shown in FIG. 3b. Here, the applied gain adjustments are shown as straight lines A₁, A₂, A₃, A₄ of different slopes superimposed on the audio waveform, and the corresponding adjustments to the amplitude of the signal can be seen. The adjusted audio output signal 5 retains its overall characteristic shape, but the fluctuations in loudness of this signal 5 are not as pronounced as in the input audio signal 1.

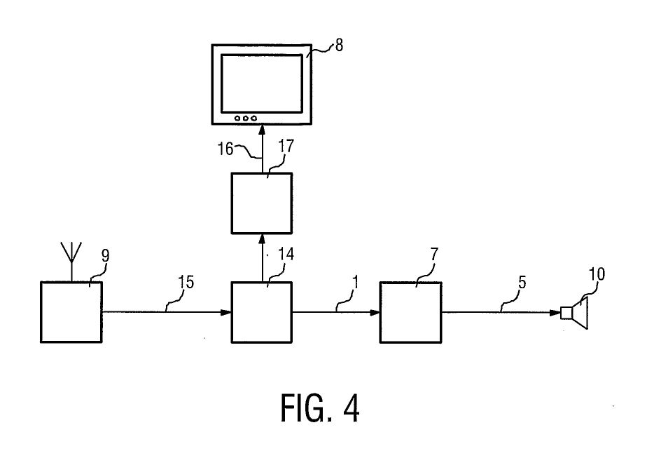

A practical application is shown in the block diagram of FIG. 4, where the system 6 for automatic loudness adjustment is incorporated into a device 7. A television signal 15 is received via an receiver 9 and is forwarded to a splitter 14, where the audio signal 1 is extracted. The audio signal 1 is passed to the automatic loudness adjustment device 7, which performs the steps described above to give an output audio signal 5 with a loudness level adjusted over time. The desired loudness level of the output audio signal can be specified by a user, not shown in the figure, using a typical user interface, for example a remote control. The adjusted audio output signal 5 is then replayed to the user on a loudspeaker 10. The loudspeaker 10 might be incorporated in the television set 8, or might be separate from the television 8. Any video signal extracted by the splitter 14 might be delayed in a delay unit 17 to compensate for any delays incurred in the automatic loudness adjustment device 7, before being forwarded as a delayed video signal 16 to the television 8. This application can be particularly useful for equalising the loudness levels which typically arise when switching between programs and commercials. The equalised loudness level will also be appreciated by users who might otherwise have difficulty following the comparatively quieter dialog in a movie featuring loud sound-effects and music soundtrack. In this situation, the automatic loudness adjustment device 7 automatically increases the loudness for the quieter parts of the dialog, while reducing, if desired, the level of loudness of the sound-effects or music. The user can simply enjoy the movie without having to constantly adjust the volume himself.

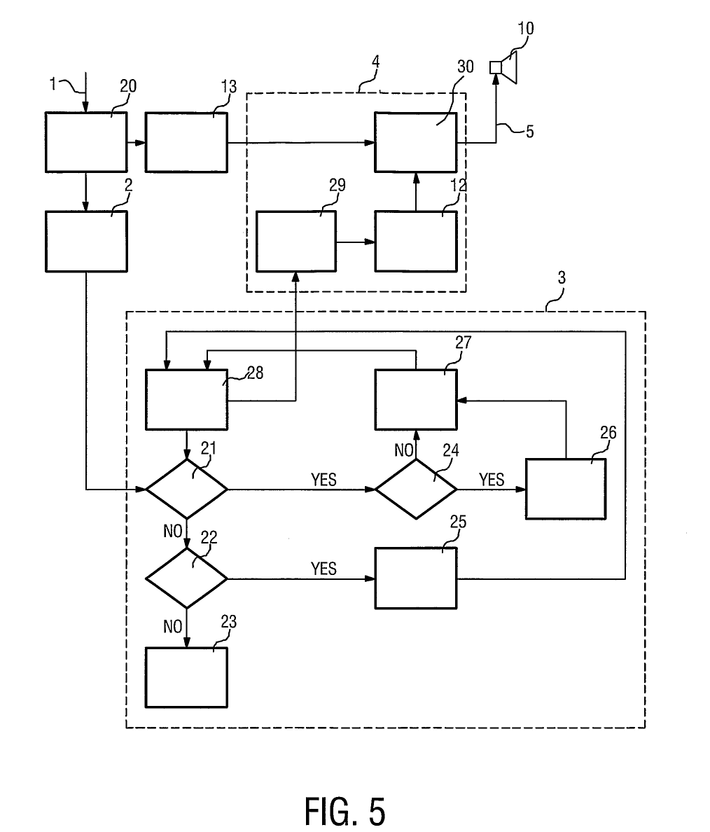

Flowcharts illustrating in more detail the processing steps involved in automatic loudness adjustment are shown in FIGS. 5-7. The flowcharts also make apparent in which unit a particular processing step may be carried out.

FIG. 5 shows the steps involved in real-time processing of an input audio signal 1. The input signal 1 is first buffered in an input buffer 20 (order of magnitude 0.1 s or smaller), since the calculation of an RMS value requires number of preceding samples. The following calculating unit 2 calculates the RMS values for the samples and compares it to the actual group mean in block 21, which is located in the identification unit 3. The group mean is initialized by a constant, e.g. 0.5, but can essentially be any real positive value. Block 21 compares the new RMS value to the actual group mean. If the new RMS value is insufficiently close to the group mean, this implies that a new group might be being formed, i.e. that the loudness of the audio signal 1 might be becoming noticeably louder or quieter. A decision block 22 checks to see if a previous RMS value has been stored or not. If not, the new RMS value is stored, otherwise a new group will be formed using the stored and new values of RMS to calculate a group mean, which in turn is stored in block 28. This group mean is now the mean of the new group. A next RMS value is calculated and compared to this group mean in block 21. If this RMS value is close to the mean, and no previous RMS value was stored, the group mean is updated in block 27. If a previous value of RMS was stored, which is checked in block 26, this implies that the single stored value deviated considerably from the group mean, but a new group is nonetheless not being established. The stored value is now also taken into consideration, along with the new RMS, in calculating the group mean in block 27. The updated group mean is stored in block 28.

The continually updated group mean values give the slope of the loudness lines L₁, L₂, L₃, L₄ for each group. The alteration unit 4 uses this information to calculate in block 29 the audio gain adjustments required to compensate for any deviation in loudness from the desired overall loudness level L.

The gain adjustments are smoothed with a low-pass filter 12, for example a first order low-pass filter 12 with normalized cut-off frequency of 0.1. Typically, a trade-off must be made between low cut-off frequency, giving improved listening quality, and the length of the required delay 13—the lower the cut-off frequency of the filter 12, the smoother the gain changes over time, but a longer delay 13 is required as a result. In a real-time application, when the delay should be kept as small as possible, the cut-off frequency of the low-pass filter 12 is chosen accordingly. In a pre-scanning application however, where the system 6 can buffer the input signal 1 for as long as it takes to perform the necessary filtering, a satisfactory value of cut-off frequency can be chosen to give smooth gain changes in the output audio signal, thereby ensuring an optimal listening experience.

Since calculating the audio gain adjustments requires some time, the input audio signal is buffered in the meantime by a series of buffers in block 13. When the alteration unit is ready with its audio gain adjustments, the output of the buffer block 13 is multiplied with the smoothed gain in a multiplication block 30 to give an audio output signal 5 with adjusted loudness level. The output audio signal can then be directed to a loudspeaker 10.

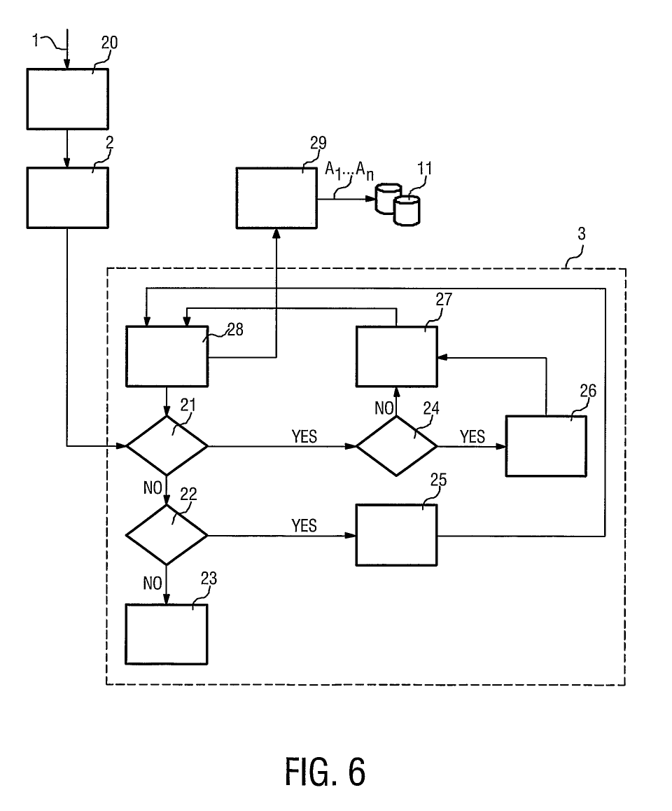

In a pre-scanning application, as shown in FIG. 6, the input audio signal 1 can be buffered for a longer time, since audio delay is no longer an issue. Here, the buffer 20 might be of the order of magnitude of 2 seconds or even longer. RMS values are calculated in a calculation unit 2 and forwarded to a first decision block 21 of the identification unit 3, whose operation has been described in FIG. 5. Only block 25 differs in that, when a new group has been identified, a process of locating the transition point between the old group and the new group is initiated. This process is described separately in more detail below.

The alteration unit 4 in this flowchart differs from the one previously described in that it only calculates the audio gain adjustments before storing these to a file or database 11. The actual multiplication of the samples of the audio input file 1 with the smoothed audio gain adjustments 31 can take place at a later time. It is also feasible, of course, in a scenario not shown in this flowchart, that the multiplication of the suitably delayed input audio signal 1 can take place after smoothing the audio gain adjustments to give an entire adjusted audio output signal which might then be stored to a file.

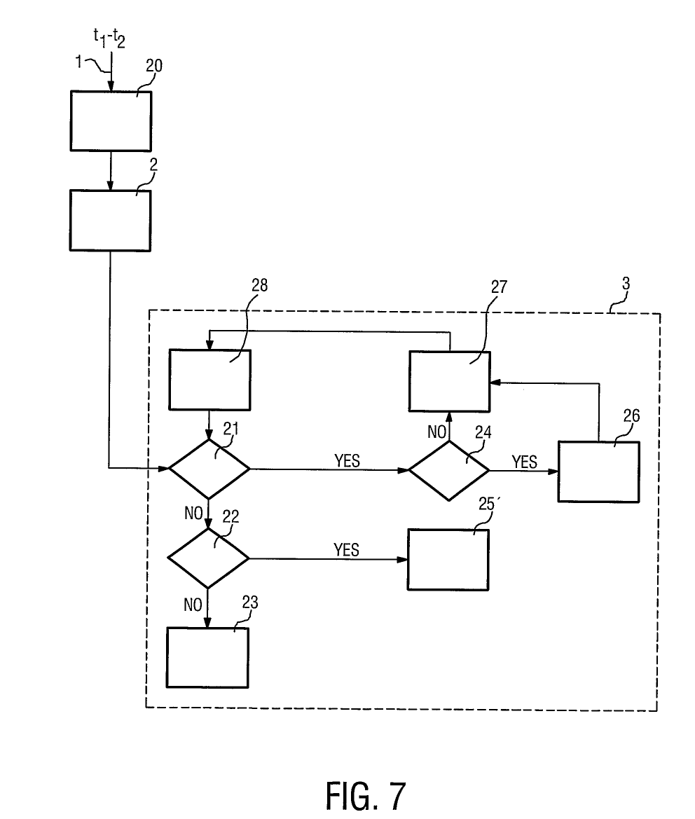

Since more time is available for processing an audio file 1 in a pre-scanning mode, this can be taken advantage of to improve the performance of the system 6 by locating with more accuracy the transition between pairs of groups. This is particularly important when the loudness of the audio signal changes abruptly between loud and quiet, since it undesirable to cut off the beginning or end of the loud part, or to unnecessarily amplify the beginning or end of a quiet part. The flowchart in FIG. 7 illustrates this process of refinement. An extract of the audio input signal 1, between times t₁ and t₂, is buffered using a relatively small buffer, e.g. 0.1 seconds. The start time of the buffer that resulted in the last RMS of the old group is given by t₁, while t2 is the end time of the buffer that resulted in the first RMS of the new group. The search is now refined by using the smaller buffer 20, so that a greater number of samples are used for calculating new RMS values. The identifier unit behaves in much the same way as previously described, with the exception of block 25′.

RMS values are calculated as before, starting at time t₁, and continuing along the group mean of the previous group, continually updating the group mean using blocks 21, 24, 26, 27 and 28. Eventually, an RMS value deviating from the group mean of the previous group will be identified by block 21 and stored in block 23. When a subsequent value of RMS, also deviating from the group mean of the previous group, is identified by blocks 21 and 22, then the block 25′ can report that the transition time is given by the start time of the block of samples used to calculate the previous stored value of RMS. The information thus pinpointed can be used in the alteration unit 4 to give accurate audio gain adjustments.

Although the present invention has been disclosed in the form of preferred embodiments and variations thereon, it will be understood that numerous additional modifications and variations could be made thereto without departing from the scope of the invention. For example, the samples of the input audio signal might be processed serially, i.e. a measure of loudness is calculated for consecutive samples, as would be the case when applying the method in a real time situation.

It is to mention that the value of gain adjustment can be produced by using a gain adjustment function, which function was derived by analysing a loudness lines (L₁, L₂, L₃, L₄).

For the sake of clarity, it is also to be understood that the use of “a” or “an” throughout this application does not exclude a plurality, and “comprising” does not exclude other steps or elements. A “unit” may comprise a number of blocks or devices, unless explicitly described as a single entity.

1. A method of automatically adjusting the loudness of an audio signal, which method comprises:
calculating loudness measures for samples of the input audio signal (1);
identifying a number of distinct loudness lines (L₁, L₂, L₃, L₄) over time among the loudness measures;
altering the samples of the input audio signal (1) according to the identified loudness lines (L₁, L₂, L₃, L₄) to give an output audio signal (5) with adjusted loudness.

2. A method according to claim 1, wherein a distinct loudness line (L₁, L₂, L₃, L₄) is identified within a group (G₁, G₂, G₃, G₄) of consecutive loudness measures, each of whose values lie within a predefined margin of tolerance for this group.

3. A method according to claim 2, wherein the samples of the input audio signal (1) are altered to compensate for deviations, from a predefined level of loudness, of the loudness lines (L₁, L₂, L₃, L₄) of groups (G₁, G₂, G₃, G₄) of consecutive loudness measures.

4. A method according to claim 2, wherein a distinct loudness line (L1, L2, L3, L4) is identified within a group (G1, G2, G3, G4) of consecutive loudness measures by applying a technique of linear or higher order interpolation or mean calculation on the loudness measures of the group (G1, G2, G3, G4).

5. A method according to claim 2, wherein a value of gain adjustment for each sample is calculated using the loudness line (L₁, L₂, L₃, L₄) of the corresponding group (G₁, G₂, G₃, G₄) of loudness measures.

6. A method according to claim 1, wherein the loudness measure for a sample of the input audio signal (1) is computed by performing a root-mean-square calculation on the input sample.

7. A method according claim 1, where the output audio signal (5) with adjusted loudness is stored in an audio file (10).

8. A method for preparing an audio signal (1) for future automatic loudness adjustment, where loudness lines (L₁, L₂, L₃, L₄) and optionally gain adjustment values are identified for the input audio signal (1) using a method of claim 1, and information describing the identified loudness lines (L₁, L₂, L₃, L₄) and/or corresponding gain adjustment values are stored in a form suitable for application at a later time.

9. A method according to claim 8, where the information describing the identified loudness lines (L₁, L₂, L₃, L₄) and/or gain adjustment values is stored together with the input audio signal (1) in an audio file (10).

10. A system (6) for automatic adjustment of the loudness of an audio signal said system comprising:
a calculation unit (2) for calculating loudness measures for samples of the input audio signal (1);
an identifier unit (3) for identifying a number of distinct loudness lines (L₁, L₂, L₃, L₄) among the loudness measures;
and an alteration unit (4) for altering the samples of the input audio signal (1) according to the identified loudness lines (L₁, L₂, L₃, L₄) to give an output audio signal (5) with adjusted loudness.

11. An audio processing device (7) for adjusting the loudness of an audio signal (1) comprising a system for automatic loudness adjustment according to claim 10.

12. An audio processing device (7) comprising a retrieval unit for retrieving previously identified loudness lines (L₁, L₂, L₃, L₄) and/or gain adjustment values for an audio signal, and an alteration unit for altering the samples of the input audio signal (1) according to the identified loudness lines (L₁, L₂, L₃, L₄) to give an output audio signal (5) with adjusted loudness.

13. A computer program product directly loadable into the memory of a programmable audio processing device (7) comprising software code portions for performing the steps of a method according to claim 1 when said product is run on the audio processing device (7).

14. A memory medium storing an audio file (10), comprising an audio input signal (1) and information describing the identified loudness lines (L₁, L₂, L₃, L₄) and/or gain values, generated using a method according to claim 8.

15. A memory medium storing an audio file (10) comprising an adjusted audio signal (5) generated using a method according to claim 7.
